(19) United States
(12) Patent Application Publication
(10) Pub. No.: US 2012/0312350 A1
(43) Pub. Date: Dec. 13, 2012

(54) Solar cell roof system having a plurality of solar modules

(76) Inventors: Thomas BUETTNER, Jena (DE); Karsten Funk, Weimar (DE); Uwe Risto, Erfurt (DE)

(21) Appl. No.: 13/491,144

(22) Filed: Jun. 7, 2012

(30) Foreign Application Priority Data
Jun. 8, 2011 (DE) 10 2011 077 229.4

(51) Int. Cl. H01L 31/052

(52) U.S. Cl. 136/246

(57) ABSTRACT

A solar cell roof system having a plurality of solar modules, of which at least some are to be installed in interconnected manner on top of each other in order to provide protection from rain; in addition, air conveyance arrangement for the supply of ambient air behind the rear side of the solar module are provided in or on at least one edge of the solar modules to be installed on top of one another, this edge being a lower edge in the normal position.

### RELATED APPLICATION INFORMATION

The present application claims priority to and the benefit of German patent application no. 10 2011 077 229.4, which was filed in Germany on Jun. 8, 2011, the disclosure of which is incorporated herein by reference.

### FIELD OF THE INVENTION

The present invention relates to a solar cell roof system having a plurality of solar modules, of which at least a few are to be installed on top of each other in interconnected manner in order to provide protection from rain.

### BACKGROUND INFORMATION

Photovoltaic modules (PV modules) encompass solar cells or photoelectrically active layers, which convert light into electrical current. These modules are able to be aligned on the ground or on roofs of buildings with the aid of frames, and be integrated into building shells. In an integration into the building shell, the solar modules can assume tasks of the building shell, e.g., aid in the protection from the weather, especially in water drainage when it is raining.

FIGS. 1 and 2 show two variants of a solar cell roof system installed integrated into the roof. Both systems are set up the same way in terms of construction and therefore denoted by numeral 1 in both figures. Each is made up of a plurality of solar modules 3, which overlap in the manner of roof shingles and are integrated into a roof cover having conventional cover elements 5. Solar cells 3 and cover elements 5 rest on a furring 7 in the manner illustrated, which in turn is situated over a sealing skin 9 and a damping layer 11 on a support structure (not shown) of the roof. The development according to FIG. 2 differs from the development according to FIG. 1 in that a rear ventilation was realized. Here, the air enters at the lowest module and streams to the uppermost module along the rear of the modules. In FIG. 2 this is symbolized by arrows L at the lower end of the illustrated roof section and below solar cells 3, while the water draining via solar module 3 has been symbolized by arrows W in FIG. 1. The warmed air must then escape in the upper roof region.

In some cases these systems are also configured completely without rear ventilation since this ventilation is especially complex when the solar cell roof system is implemented as water-carrying layer (as shown in FIG. 1). The great warming of the solar module has a negative effect on the efficiency, since the output of the PV modules decreases as the temperature rises.

### SUMMARY OF THE INVENTION

The exemplary embodiments and/or exemplary methods of the present invention provide a solar cell roof system having the features described herein. Expedient refinements of the inventive idea are the subject matter of the respective dependent claims. The term “roof system” also encompasses facade systems which assume the tasks of a housing shell outside of a roof, especially protection from the climate.

In one development of the exemplary embodiments and/or exemplary methods of the present invention, the air-conveyance arrangement according to the present invention are provided in the lower edge and the opposite-lying upper edge of the solar module. Furthermore, the air conveyance arrangement, in particular, are configured in or close to a frame part of the solar module.

In one further development, the air-conveyance arrangement include a cut-out in the frame part, especially an individual cut-out in a lower edge frame part and an upper edge upper edge frame part, of the solar module. In a still further development, the air-conveyance arrangement is assigned water-repelling arrangement for repelling water that is traveling in an upward direction. In particular, the water-repelling arrangement include wedge-shaped forms or supplementary components in the form of wedges on an upper edge frame part of the solar module.

In another development of the exemplary embodiments and/or exemplary methods of the present invention, the roof system according to the present invention has module plug-connector profiles, which simultaneously provide correct positioning of the solar modules to be installed on top of each other. Furthermore, the module plug connector profiles simultaneously form the supplementary components implemented in the form of wedges. Finally, the provided system advantageously has a termination hood for mounting above a solar module, which has a V- or U-shaped air discharge channel for releasing air from behind the rear side of the solar module, while simultaneously preventing the entry of rain water; it also has plug-connection arrangement for plugging into an edge of the solar module. Moreover, a useful solar cell roof system has a lower edge plug-connector profile provided with cut-outs that serve as air conveyance arrangement, for mounting under a lowermost solar module of the solar cell roof system.

Further advantages and advantageous refinements of the subject matters of the exemplary embodiments and/or exemplary methods of the present invention are illustrated by the drawing and elucidated in the following description. In this context, it should be noted that the drawing has only descriptive character and is not intended to limit the invention in any form.

### BRIEF DESCRIPTION OF THE DRAWINGS

FIG. 1 shows a schematic cross-sectional view of a roof structure having a known solar cell roof system.

FIG. 2 shows another schematic cross-sectional view of a roof structure having a known solar cell roof system.

FIG. 3 shows a schematic cross-sectional view of a roof structure having a solar cell roof system according to the present invention.

FIG. 4 shows a perspective view (detail view) of a specific development of the solar cell roof system according to the present invention.

FIG. 5 shows a perspective view (detail view) of a module plug connector profile of a specific development of the solar cell roof system according to the present invention.

FIG. 6 shows a schematic cross-sectional view of a termination hood of a specific embodiment of the solar cell roof system according to the present invention.

FIG. 7 shows a perspective view (detail view) of a special module plug-connector profile of a specific embodiment of the solar cell roof system according to the present invention.

### DETAILED DESCRIPTION

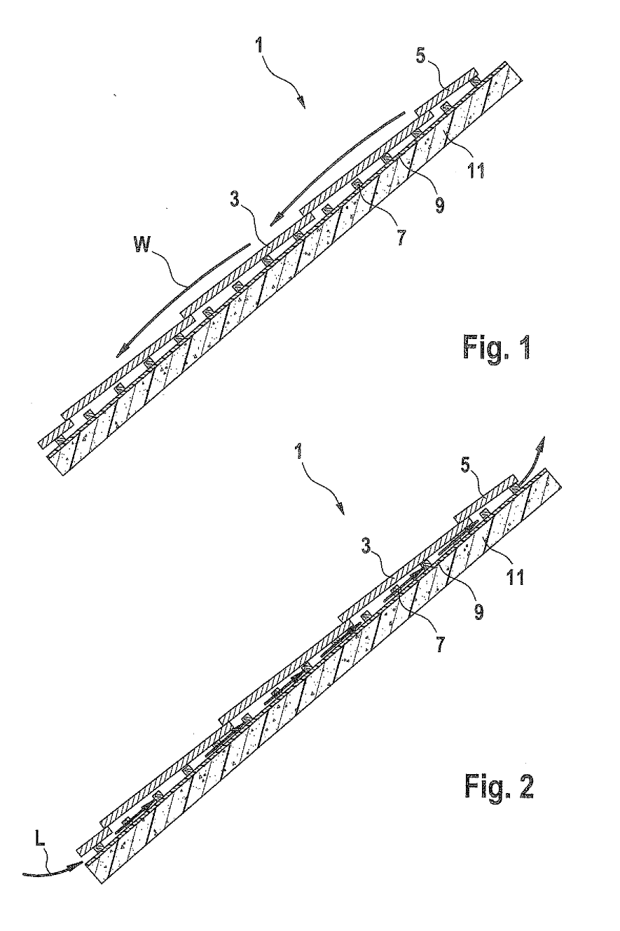

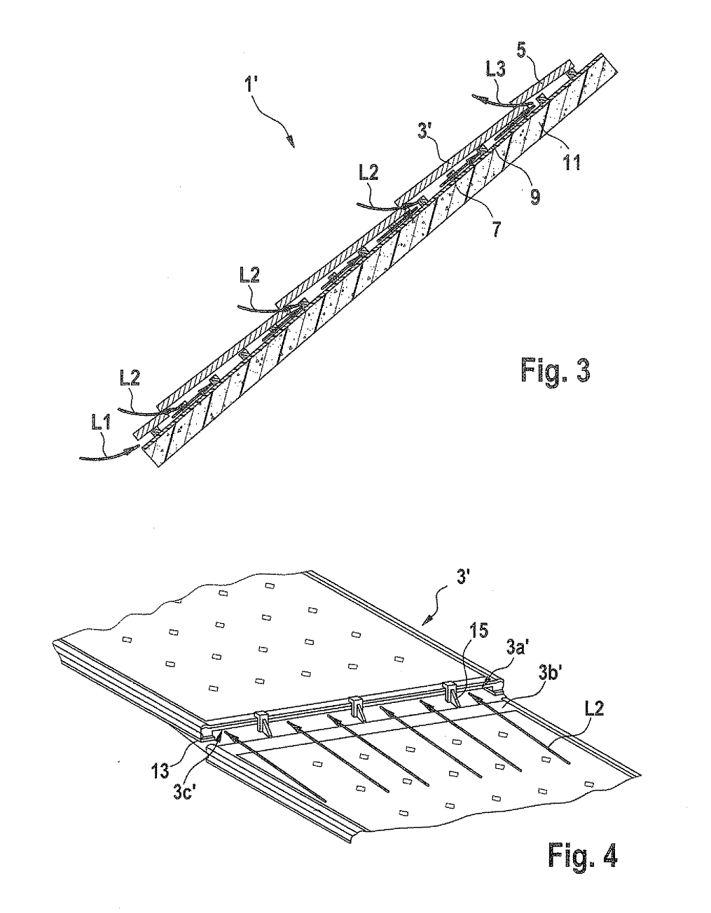

FIG. 3, in accordance with the illustration in FIGS. 1 and 2, schematically illustrates the structure of a solar-cell roof system 1′ according to the exemplary embodiments and/or exemplary methods of the present invention, in which identical or functionally equivalent components have been denoted by the same numerals as in FIG. 1 and FIG. 2 and are not discussed here again. Roof system 1′ differs from roof system 1 according to FIG. 2 in that an air stream L1 enters behind the solar cell module not only underneath the system, i.e., below lowest solar cell module 3′, but additional air streams L2 also enter at the lower edges of the individual modules or between their upper edge and lower edge of the module disposed above. This is achieved by a constructive configuration and installation of solar cell module 3′ that differs from the placement in FIG. 2, and utilizes special air conveyance arrangement (not visible in FIG. 3). Furthermore, an air exit L3 is situated directly at the upper edge of uppermost solar cell module 3′, i.e., adjacent to abutting roof cover element 5, in the provided system. The arrangement used for this purpose are also shown in other figures and described further below.

FIG. 4 shows in greater detail the adjacently located edge regions of two solar modules 3′ of a solar-cell roof system 1′ of the type illustrated in FIG. 3. Like an adjacent upper edge frame part 3b′ of the adjacent solar cell module abutting below, a lower-edge frame part 3a′ also includes a cut-out 3c′, so that an air stream L2 is able to penetrate between them. The adjacent solar cell modules are connected via a module plug connector profile 13, on which a plurality of plug connectors 15 are mounted for the electrical connection and for the mechanical fixation of the individual module.

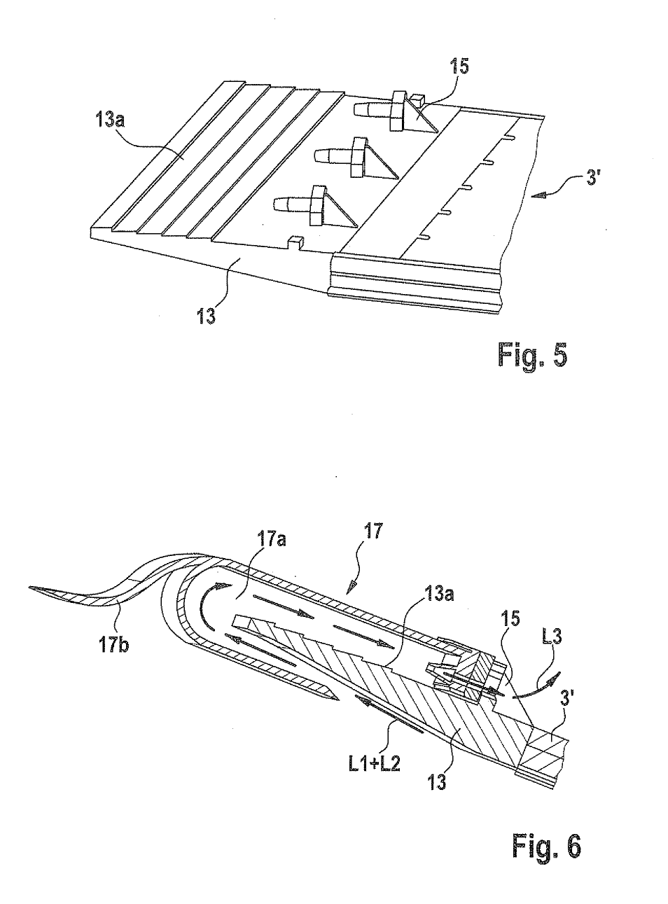

FIG. 5 shows a perspective detail view of such a module plug connector profile 13 and plug connectors 15 mounted thereon in greater detail. It is obvious that the cross-section of profile 13 has a flat, trapezoidal configuration, so that its overall shape could be considered wedge-shaped. A plurality of small, wedge-shaped forms 13a is provided on its top surface, which during use are intended to largely prevent rain water from traveling in an upward direction between profile 13 and solar cell module 3′ mounted thereon, behind its rear side.

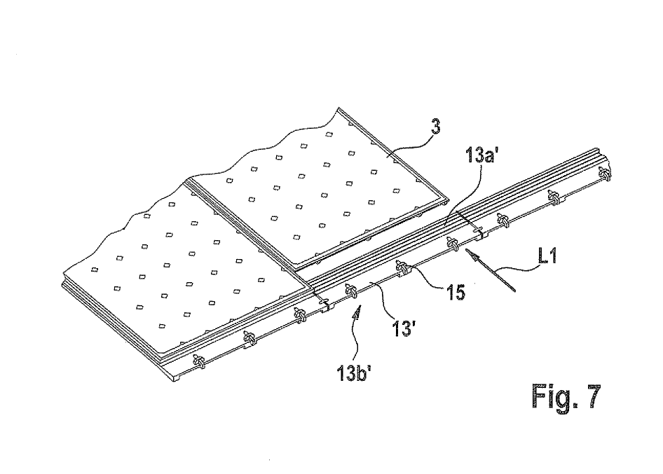

FIG. 6 shows module plug-connector profile 13 including one of the plug connectors 15 once again in cross-section, i.e., in its use as plug connector arrangement in order to place a termination hood 17 on top of the upper edge of solar cell roof system 1′. This termination hood 17 guides air stream L3 traveling from the rear side of the solar-cell roof system, while it simultaneously prevents the entry of rain water. For this purpose, it includes an air channel 17a, which has a U-shaped cross-section and is formed by the inclusion of module plug connector profile 13. A premolded extension 17b ensures a waterproof fit under a roof cover element (not shown) abutting the solar-cell roof system at the top.

A perspective detail view in FIG. 7 shows as additional component of the particular development of the present invention elucidated here, special plug connector profiles 13′, which are to be used as lowest profile of a solar-cell roof system and for this purpose are provided with cut-outs 13a′ at the lower edge, which enable the entry of an air stream L1 behind the rear side of the roof system, from the direction of its lower edge.

Additional developments and implementations of the method and device described merely by way of example, result within the actions of one skilled in the art.

What is claimed is:

1. A solar cell roof system, comprising:
a plurality of solar modules, at least a few of which are to be installed in an interconnected manner on top of each other so as to provide protection from rain; and
an air conveyance arrangement for supplying ambient air behind the rear side of the solar module, wherein the air conveyance arrangement is provided in or on at least one edge of the solar modules to be installed on top of each another, and wherein the edge is a lower edge in the normal position.

2. The solar cell roof system of claim 1, wherein the air conveyance arrangement is provided in the lower edge and the opposite-lying upper edge of the solar module.

3. The solar cell roof system of claim 1, wherein the air conveyance arrangement is configured in a frame part of the solar module.

4. The solar cell roof system of claim 3, wherein the air conveyance arrangement includes a cut-out in the frame part, which is an individual cut-out in a lower edge frame part and an upper edge frame part of the solar module.

5. The solar cell roof system of claim 1, wherein a water-repelling arrangement to repel upward-traveling water is assigned to the air conveyance arrangement.

6. The solar cell roof system of claim 5, wherein the water-repelling arrangement includes wedge-shaped forms or supplementary parts configured in a wedge-shape on an upper edge frame part of the solar module.

7. The solar cell roof system of claim 1, further comprising:
module plug connector profiles, which are simultaneously configured for the correct positioning of the solar modules to be installed on top of each other.

8. The solar cell roof system of claim 7, wherein the module plug connector profiles simultaneously form the wedge-shaped supplementary components.

9. A solar cell roof system of claim 1, further comprising:
a termination hood to be installed over a solar module, wherein the termination hood has a V-shaped or a U-shaped air discharge channel for discharging air from behind the rear side of the individual solar module, while simultaneously preventing the entry of rain water, and it includes a plug-connector arrangement for plugging into an edge of the solar module.

10. The solar cell roof system of claim 7, further comprising:
a lower-edge plug connector profile having cut-outs used as an air conveyance arrangement, to be installed underneath a lowermost solar module of the solar cell roof system.
